(19) United States
(12) Patent Application Publication
(10) Pub. No.: US 2008/0296606 A1
(43) Pub. Date: Dec. 4, 2008

(54) Electronic Module and Chip Card With Indicator Light

(76) Inventors: Stephane Ottobon, St Cyr Sur Mer (FR); Thierry Karlisch, La Ciotat (FR); Thierry Laviron, Peynier (FR); Lucile Dossetto, La Ciotat (FR)

Correspondence Address: BUCHANAN, INGERSOLL & ROONEY PC, POST OFFICE BOX 1404, ALEXANDRIA, VA, 22313-1404, US

(21) Appl. No.: 11/887,049

(22) PCT Filed: Mar. 17, 2006
(86) PCT No.: PCT/EP2006/060817

§ 371 Date: Sep. 24, 2007

(30) Foreign Application Priority Data
Mar. 22, 2005 (FR) 0502844

(51) Int. Cl. H01L 33/00; H01L 21/56

(52) U.S. Cl. 257/100; 438/26; 313/499; 257/E33.059; 257/E21.502

(57) ABSTRACT

The invention generally relates to devices comprising semiconductor chips. More specifically, the invention relates to an electronic module (1) comprising at least one integrated circuit chip (10) which is connected to the conductor tracks of an insulating support and at least one light-emitting diode (16). According to one aspect of the invention, the assembly formed by the integrated circuit (10) and the light-emitting diode (16) is coated with a translucent resin (32), thereby forming an element for the mechanical protection of the assembly and for the transmission of the light emitted by the diode (16). According to another aspect of the invention, the coated assembly comprises at least one indicator light (LED) and a radio-frequency coil (preferably in the module).

The present invention relates to the field of devices comprising semiconductor chips and embodying a function of indicator light.

The present invention more particularly relates to the manufacturing of an electronic device comprising an integrated circuit chip and an indicator light of the electroluminescent diode type. It more particularly applies to the indication of activity in contact or contactless electronic devices such as chip cards, or USB (Universal Serial Bus keys)°.

As mobile devices and personal terminals which comprise several movable modules or wireless connections are emerging, it is difficult to know and control the operation of the various interacting elements. There are USB keys which make it possible to report the data transfer. On the contrary, as regards cards, there is no reliable indicator showing that the card is effectively communicating.

Some solutions provide data transfer indicators reported to card readers, for example.

Patent application WO 02/023 357 describes a method and a device for the transfer of data between a USB port and a chip card connected to this port via a reader. The aim of this invention is to generate a signal driving an electroluminescent diode and reflecting the USB transaction activity. The electroluminescent diode is fastened on the card reader, the reader having a USB connector. In this solution and generally speaking, the indicator light is an integral part of the card reader and is separated from the chip embodying the data transfer.

These solutions are not satisfactory because the indicator light of the reader is not a reliable control indicator of the activity of data communication by the card.

The present invention is intended to remedy the prior art disadvantages by providing an indicator light reliably restituting the activity of the card or any other device and which is simple and as economically manufactured as possible.

According to a first aspect, the invention consists in directly associating an indicator with an integrated circuit card (preferably as regards a chip card module) the activity of which must be controlled. Therefore, a common mechanical protection of the integrated circuit chip and the indicator is carried out, which also ensures the transmission of the light emitted by the electroluminescent diode.

According to a second aspect, the invention also consists in associating an indicator light (LED) and a radio frequency aerial (preferably as regards a module of the contactless chip card module type). Besides, a common mechanical protection of the indicator, the electric connections from the indicator to the aerial and if need be at least partially or totally, of the aerial turns also ensures the transmission of the light emitted by the electroluminescent diode.

The invention is economical because it can use the manufacturing chip card modules technology. Besides, only one coating is enough to ensure the mechanical protection and a waveguide function, preferably with a lenticular or a bulging form.

The invention also has the advantage of satisfying bending/torsion mechanical resistance criteria which are specific to the chip card technology more particularly thanks to the positioning of the diode close to the integrated circuit chip and the common coating.

The connection of the electroluminescent diode LED can be carried out on the same dielectric film which is provided as a film coil to manufacture a chip card module.

The dielectric support film can already include preferably conductive tracks which can be all or part of an electric circuit (coil and/or capacity and/or resistance) and/or only ohmic contact pads or connection tracks intended to receive a junction such as a welding or an adhesive conductive material.

At least one LED and if need be an unpackaged integrated circuit chip can be reported and connected close to the LED at the various components report and connection stations. In principle, an electroluminescent diode can be 2 to 5 times less bulky than an integrated circuit chip even though it can be in the form of a surface mounted component (SMC).

The electric assembly selected with the LED can be coated at the coating station within one operation and with the same translucent protection.

The dielectric film can be replaced by any other insulating support such as a polymer sheet, a paper sheet, a printed circuit substrate; the support can have dimensions equal to or greater than a contact or contactless chip card module.

The conductive tracks can be made by any known method and particularly by engraving, screen printing, deposition of a conductor and jet of conductive material.

Therefore, the object of the invention is an electronic module comprising at least one unpackaged integrated circuit chip connected to conductive tracks of an insulating support by first electric connections and at least one electroluminescent diode connected to the conductive tracks by second electric connections, characterized in that the assembly composed of the integrated circuit, the electroluminescent diode, the first and second electric connections is coated with a translucent resin forming an element for the mechanical protection of said assembly and for the transmission of the light emitted by said electroluminescent diode.

Another object of the invention is also an electronic module comprising at least one electroluminescent diode connected to conductive tracks of an insulating support forming at least one electromagnetic coil by means of second electric connections, characterized in that the assembly formed by at least the electroluminescent diode 16, the second electric connections and at least partially the coil is coated with a translucent resin 32 forming an element for the mechanical protection of said assembly and for the transmission of the light emitted by said electroluminescent diode.

Thus, it is quite practical and simple to manufacture a device having an indicator light and to insert it in another supporting body (card body, USB key) without any other electric connection because of the presence of a coil within the module.

In one embodiment, said electroluminescent diode is a chip of semiconductor material obtained directly from a sawn wafer.

Said electroluminescent diode is also connected in parallel with said integrated circuit.

In one embodiment said protection is bulging.

In a particular embodiment, said bulging forms a focal point in the plan of said electroluminescent diode.

More particularly, said resin is translucent and/or comprises pigments, the transmission band of which includes the emission wavelength of said electroluminescent diode.

Said resin possibly comprises dopants having remanence property and an excitation band including the emission wavelength of said electroluminescent diode, the dopant being capable of being loaded with energy upon the emission of said electroluminescent diode and restituting this energy during a time interval, in the form of a light having one or several own wavelengths.

In one embodiment said module further comprises a resistance in series with said electroluminescent diode.

According to the invention, said integrated circuit is a contactless chip.

In one embodiment, said electroluminescent diode is directly supplied by an induction loop included or not in said module.

More particularly, said module includes a magnetic field detector and a control circuit of said electroluminescent diode depending on the detection of said electromagnetic field.

Said control circuit can deliver an electric signal to said electroluminescent diode, the frequency of which depends on the intensity of the detected electromagnetic field.

In an alternative embodiment, said electroluminescent diode is directly connected to the supply terminals of said module.

The invention also relates to an electronic device comprising such an electronic module.

In an embodiment, the device is of the chip card type and it includes a plastic support having an apparent cavity in which said electronic module is embedded.

In an alternative embodiment, the chip of said electronic module has a contactless communication function (radio frequency for instance) and the electronic module is buried in the body of said chip card during the card lamination steps.

Said plastic support eventually forms a wave guide capable of transmitting the light emitted by said electroluminescent diode.

Said device can simply consist of a USB key totally or partially manufactured according to the chip card technology.

The present invention also relates to a method for manufacturing an electronic module intended for an electronic device, the module comprising at least one integrated circuit chip connected to conductive tracks of an insulating support and at least one electroluminescent diode. The method includes a step of coating the assembly composed of at least the integrated circuit, the electroluminescent diode, and their respective connections to the conductive tracks of the module by an insulating and translucent resin.

According to an implementation during the last encapsulation step, said resin is deposited so as to have a radius of curvature, for example by dispensing the resin in the form of drops (glob top). The resin can also be molded from the cast while being centered upon the assembly. Preferably the resin has a bulging or lenticular shape centered on the assembly of the electric circuit or electronic circuit to be protected.

The invention will be better understood upon reading the description given hereafter only as an explanation of an embodiment of the invention with reference to the appended figures, where,

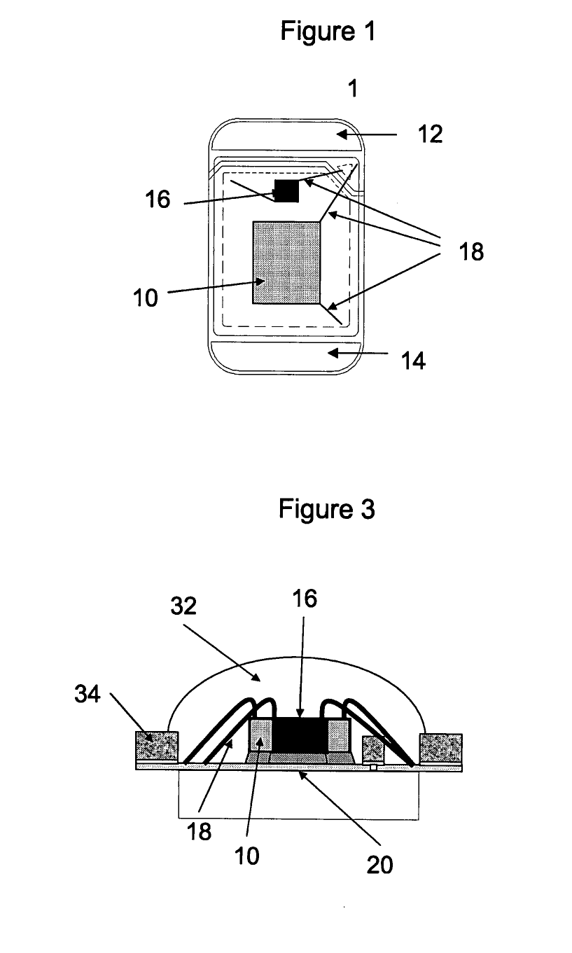

FIG. 1 shows the assembling diagram of contactless chip card module in an embodiment of the invention;

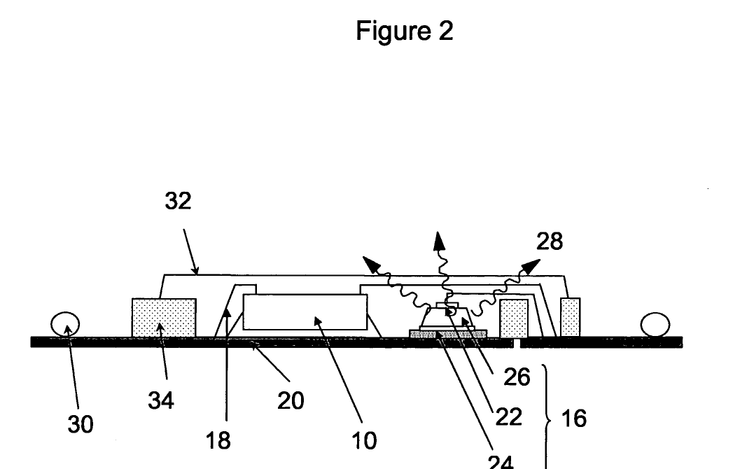

FIG. 2 illustrates the architecture of a chip card module embodied according to this invention;

FIG. 3 illustrates a coating resin dome shaped in an embodiment of the invention.

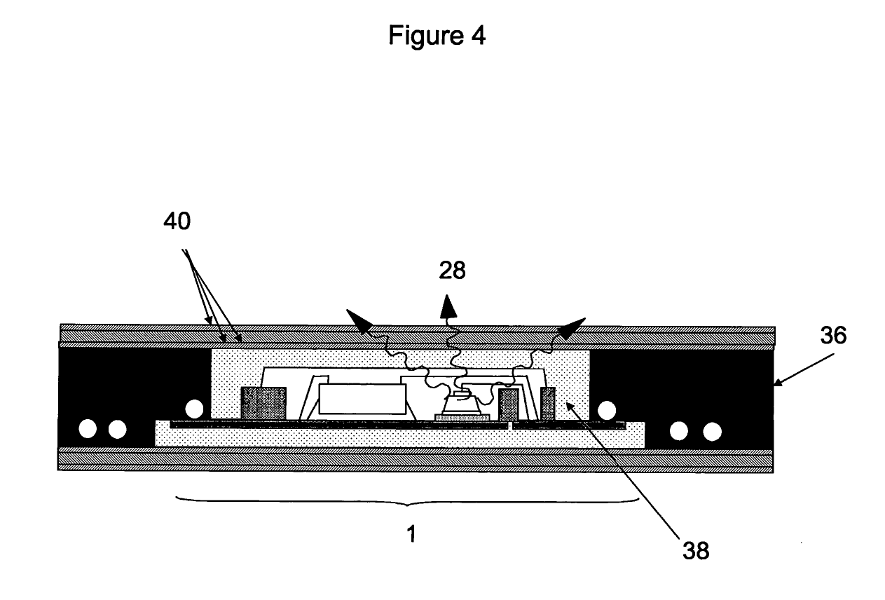

FIG. 4 shows an exemplary chip card implementing this invention; and

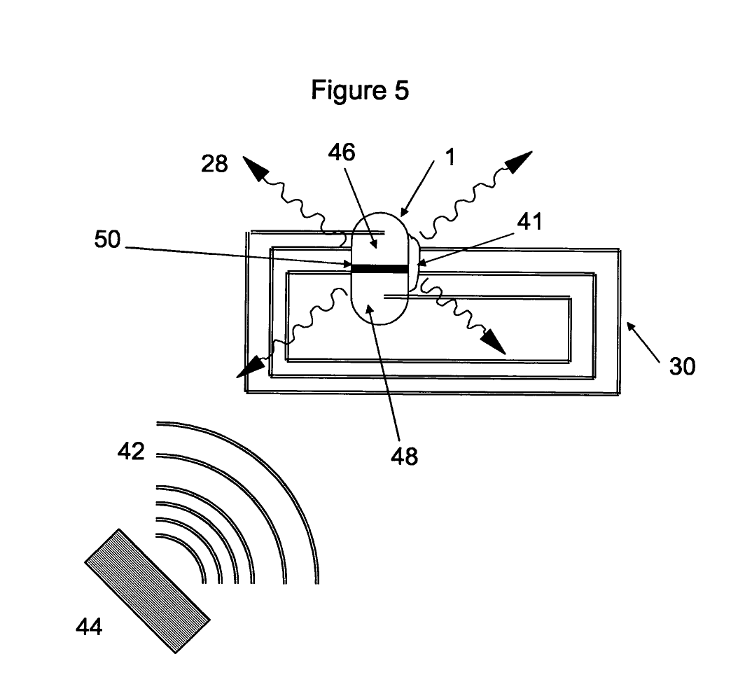

FIG. 5 illustrates one utilization of the invention.

Referring now to FIG. 1, module 1 of the contactless chip includes the contactless chip 10, two connections 12 and 14, and one electroluminescent diode 16. The diode 16 is integrated in module 1 in the form of a semiconductor chip obtained directly from a semiconductor wafer and has an operating voltage of 3 to 5 V. Electric connections 18, for instance gold wires, make it possible to electrically interconnect the diode 16 and the chip 10.

The electroluminescent diode 16 is selected to be compatible, as regards its voltage and intensity, with the energy which can be transferred in the case of contactless chip, a few volts and a few milliamperes are the currently used values.

Finally, a resistance mounted in series with the electroluminescent diode 16 may be added so as to limit the intensity circulating in the electroluminescent diode.

In a similar embodiment, the chip 10 used in the module is a chip operating by means of an electric contact mounted in parallel, from which several electroluminescent diodes 16 are connected and emit in the visible spectrum (400 to 750 nm) or the invisible spectrum, for instance the ultraviolet spectrum (10 to 400 nm). Electroluminescent diodes 16 are possibly selected to have different colors, which gives an increased legibility of the information they transmit: for example, one diode gives information on module 1 energy supply, another on the output activity, and a third one on the incoming activity in the module.

With reference to FIG. 2, the integrated circuit or chip 10 and the electroluminescent diode 16 are electrically inter-connected using an insulating substrate comprising a conductive circuit 20 made of copper. Conventional methods for assembling the diode 16 and/or chip 10 are used to embody these electric connections: welding of gold wires 18 between components 10 and 16 and conductive parts 20 of the substrate, the gluing of a conductor, a flip chip (chip turned upside down, not shown). The respective connections of the diode or of the integrated circuit chip to the conductive tracks of the module substrate may include adhesive conductive material.

The electroluminescent diode 16 is connected in parallel with chip 10. This substrate is an insulating support which can be a dielectric, polymer sheets, paper, a printed circuit support . . . .

The electroluminescent diode 16 is composed of an optoelectronic semiconductor 26 and one anode 22 and one cathode 24 on either side on the semiconductor 26. The voltage applied by the anode and the cathode to the semiconductor excites the latter which then emits light 28.

The prior art includes other electroluminescent diode structures, some of which integrate a mirror (a coat of aluminum) in order to increase the brightness.

The device also includes an aerial 30 of the induction loop type which converts the electromagnetic energy from the environment into electric energy required for the operation of the chip and other components. The aerial 30 is also used for transmitting data at high frequencies (13.56 MHz or 915 MHz for instance). The aerial is directly located in the chip card body and is electrically connected to the module supply terminals 1. In an alternative solution, the device includes two aerials 30, one being dedicated to low frequencies of the order of a few hertz for the conversion of the electromagnetic field energy into electric energy and the second one being dedicated to high frequencies for the transfer of data.

In one embodiment, the aerial 30 is directly integrated in module 1, for instance on the substrate.

The chip 10 drives the electroluminescent diode 16 by regulating the voltage at the terminal and/or the intensity going through the electroluminescent diode 16. This driving operation can be carried out depending on various policies, according to the information that is desired or really transmitted to the user via the lighting of the electroluminescent diode 16. For instance, when the chip 10 receives or emits data through aerial 30, it supplies in parallel the electroluminescent diode which gets lit.

All the policies can be considered:

regulating the supply of the electroluminescent diode depending on the data transfer rate, depending on transactions. Data transaction means any electric exchange of data or information or by radio frequency.

placing the electroluminescent diode in “pass” position that is lit, as soon as the chip is energy supplied. This policy more particularly makes it possible to inform the user that its conductive chip card is entering the electromagnetic field of a reader.

lighting the electroluminescent diode only upon the transfer of some data (encrypted data for instance),

The electroluminescent diode can also be supplied intermittently by the chip. The blinking frequency of the electroluminescent diode can be used as an indicator of the data transfer rate or of the intensity of the electromagnetic field detected by the aerial (the farther you are from the reader, the lower the blinking frequency is).

In a particularly simple embodiment, the electroluminescent diode 16 is directly connected to the aerial 30, i.e. it is not connected to the chip. Then when the chip card is placed in an electromagnetic field, the diode 16 is supplied by the current converted from the electromagnetic field by the aerial and the diode thus gets lit.

Now referring to FIG. 2, an electrically insulating and translucent resin 32 is placed at the same time on the chip 10, the electroluminescent diode 16 and the weldings 18. The word “translucent” means the capacity of the resin to let light through, even partially.

The coating of these elements (10, 16, 18) with resin can be carried out by known methods, for example the filling technique using two resins having different viscosities (also called the Dam and Fill technique).

In the prior art, the utility of this resin was simple: the protection of coated elements (chip and weldings) against environmental, mechanical, or electric damages. In the present invention, this resin 32 has an additional advantage: it is a means of diffusing the light emitted by the diode. By varying the various parameters (viscosity of resin, flowing speed, polymerization to block the spreading of the resin), the radius of curvature is affected, which can make it possible to obtain a lens for the transmission of the whole or part of the light emitted by the electroluminescent diode 16.

It is possible to use a resin, the conductive tracks of which can be activated by means of a laser to carry out electric connections.

The resin 32 is chosen to be translucent to obtain a better transmission of light; it can more particularly be based on silicone, epoxy, and polyurethane.

According to various considered embodiments, the resin 32 includes dopants which secure spreading of light and have pigments, the transmission band of which includes the emission wavelength of the electroluminescent diode.

According to one embodiment, the resin 32 has remanence properties, for instance use of dopants having absorption and remission properties as this is described in greater details in document EP 265 323. The dopants are selected to have an absorption band including the emission wavelength of the electroluminescent diode 16: the dopants are loaded with energy upon the emission of the electroluminescent diode and restitute this energy as light at one or several wavelengths which are their own.

This remanence property has several advantages for this invention:

reducing the consumption of energy if need be. Appropriately selecting the dopants so that they re-emit with a wavelength in the visible spectrum, for instance which is substantially equal to the emission wavelength of the electroluminescent diode used, the latter cannot be lit but intermittently since between “lit” periods of time, the dopants re-emit and give continuity to the light indication of the card.

continuing the emission of light when the contactless chip has been removed from the electromagnetic field of the reader and demonstrating the prior utilization of the card, for instance without the owner knowing it. The dopants are chosen to have long remanence properties, i.e. they re-emit the absorbed energy for a long period of time, for example several minutes in the previously mentioned examples.

Now referring to FIG. 3, the resin 32 is given the desired shape which makes it possible to control the light path. For instance, the resin is shaped like a dome which is close to the shape of an optical lens. This is made possible thanks to the so called “dispense” deposition technique in which the resin is deposited using a needle along a desired path. Then it is easy to give it the requested shape.

It is possible to modify the optical parameters of the resin coating by varying the thickness and viscosity parameters of the resin, and on the radius of curvature of the outer layer. It can be envisaged to modify the position of the point/focal plan of the optical assembly constituted by the resin with respect to the electroluminescent diode to vary the diffusion cone of the emitted light.

The light electronic module 1 thus created is integrated into the chip card body (having a thickness lower than 1 mm). Several techniques exist.

Referring now to FIG. 4, the body 36 of the chip card of plastic type includes a cavity 38. The insertion operation consists in integrating the electronic module 1 in the cavity. The cavity 38 may include a filling material such as an adhesive. This filling material is preferably chosen to be translucent. Within the scope of a contactless chip card, translucent/transparent polymer sheets 40 are laminated on the card, which thus ensures a mechanical protection and the transmission of the light emitted. In the Example of FIG. 4, the coating is made of three stacked sheets 40. Using opaque polymer sheets is also possible, in which case they are extremely thin which makes it possible for the whole or a part of the light to go through: these very thin sheets can be considered as being translucent. The quantity of light passing through can be low so the electroluminescent diode is then more visible in the dark.

In an alternative solution the chip 10 is buried in the chip card body 36 during the creation process of the contactless chip card by lamination of the various layers.

Generally speaking the body of the card or of the object containing the module is designed totally or partially so as to make it possible for the light emitted by the electroluminescent diode of module 1 to go through, which is integrated for example through the utilization of a transparent or translucent material: transparent card body, translucent polymer sheets.

In one embodiment, the plastic support of the card is designed as a light wave guide, which makes it possible to guide the light to the requested place. For instance the light is guided towards the outer wafer of a contact card when this one is plugged in a reader and the chip is not visible.

To embody this wave guide, the interface between the card body 36 and the upper and lower layers 40 is partially reflecting which makes it possible to propagate waves in the card body 36. Then, it is particularly of interest that this interface has a high reflecting power (index higher than 50%, for example 80%) which thus limits the signal attenuation during the propagation. As the rays are transmitted in the layers 40, they can be absorbed or even transmitted towards the outside of the card.

In one embodiment an aluminum coating may be used on either side of the card body 38. The light wave is then totally reflected without the light signal being attenuated.

The substrate of the electronic module 1 is also a transparent insulator upon which a conductive circuit or conductive tracks more particularly made of copper is (are) present. This particularly makes it possible for the light emitted by the electroluminescent device to be visible in the space between the contact pads of a chip card module.

In another embodiment, the substrate of module 1 has a reflecting layer of the mirror type (aluminum layer) to increase the brilliancy of the diode when seen from above.

The utilization of the present invention is multiple.

In the case of a chip card, the electroluminescent diode makes it possible to indicate any transaction carried out with a reader or even to give information on the transfer rate by using a blinking frequency of the electroluminescent diode. Several electroluminescent diode having different colors are also used to give various information.

When the chip card is contactless with reference to FIG. 5, the electroluminescent diode (41 provided with the coating resin which bulges) contained in module 1 can be used as an indicator of the presence of an electromagnetic field 42 emitted by a contactless card reader 44. The light spreads from the diode and through the resin 41. The supply aerial 30 is connected to both contact pads 46 and 48, which are electrically separated by an insulating part 50.

The invention can also be implemented in USB keys of the memory type more particularly totally or partially manufactured according to the chip card technology as per the applicant's patents. The USB module has contact pads in the USB format more particularly the contact pads are linear (they are placed adjacent to one another) and parallel. The electroluminescent diode is connected in series with a resistance between Data+ and Data− terminals of the USB contacts. In this case, the electroluminescent diode lights up when the module is supplied by the USB port.

The card can also accumulate contact functions (transmission through electric contact) and contactless functions (radio frequency). The electronic module may include two communication interfaces and include an aerial on the module as well as the conductive tracks mentioned above and electric contact pads.

In the case of a card having communication functions through electric contacts the latter is introduced into the reader and the operation activity (supply) can be visible on the card edge particularly via a previously described wave guide or through the card body and the reader if the latter is transparent.

In the case of a contactless card, the indicator gives information, in the same reliable manner, on the presence of an electromagnetic field or the transfer of data.

According to an embodiment of the electronic module, the electroluminescent diode 16 can be supplied in various ways. A diode of the SMC type (surface mounted component) can thus be used. According to this type of chip the electroluminescent diode 16 can itself be mounted on a support having connection tracks and a second protective translucent coating, said diode being connected to the module by second electric connections.

The (second) connections of the diode to the module conductive tracks which can particularly be made with the welded wire, or any other means, must be protected as well as the (first) connections of the integrated circuit chip which can be present.

Although the diode chip can be coated in the case of a SMC this is not the case for subsequent connections which connect the connections track of the SMC to the conductive tracks of a module. The invention makes it possible to protect the assembly which at least comprises the SMC, the subsequent connections and at least partially the conductive tracks of the substrate or module.

In the case where the plastic support 36 containing the module has a wave guide function as mentioned hereabove, this function can be carried out by at least one optical fiber or an equivalent device which is arranged in the support with respect to the diode to form at least one wave guide in the support 36 for the light emitted by said electroluminescent diode 16. Preferably, the wave guide can emit transversally and/or in the plane of the support.

For instance, the optical fiber can extend up to a cavity containing the coating and/or the module. The wave guide can also extend up to the coating if there is no cavity in the case where the module is buried in the support material.

It is thus possible to display any pattern, light information by the passage of the light in wave guides arranged in the support body, on a plastic support 36.

In one embodiment, the integrated circuit chip is omitted, which leaves only one electroluminescent diode (for instance as a SMC or unpackaged) on the support with conductive tracks on the support forming an electromagnetic flat aerial or coil. The coating is dispensed so as to cover the assembly composed of the diode, the diode electric connections to the tracks and at least partially the conductive tracks (or preferably totally for a good mechanical resistance of the module). Then the LED Module function is exclusively that of giving information according to the presence or the absence of an electromagnetic field.

The module can thus be used without the integrated circuit chip which more particularly embodies the communication functions. The electromagnetic aerial can be placed or not on the module and more particularly around the LED or under the LED; the LED can have various shapes or constructions. If need be the coil (aerial) can also be coated at least partially so as to have a good mechanical resistance.

This module having a LED supplied by means of a coil with or without an integrated circuit chip has the advantage of being easily introduced as an insert in the support body for instance, (having a thickness lower than 1 mm) and more particularly by lamination or injection. It does not need any connection since it can be coupled to any other coil placed in the support with no need for a connection to the support coil.

This possibility of electromagnetic coupling makes it possible to position the module in the support as desired. This LED module has the advantage of being self supportive because of its coil and it can be manufactured according to the chip card module technology.

Instead of or in addition to a passive coil mentioned above of the support body, the latter can also include a wave guide or optical fibers path preferably representing one information or several information (words, letter, figures, logo . . . ). The module or the support may include several LEDs (having different colors if need be) and coils associated so as to display different information depending on the electromagnetic frequency which it has been submitted to.

Various user information applications can be considered as an indication of a particular access according to a code of colors concerning the activated LED (among which several contained LEDs) when coming close to an electromagnetic terminal (an airport, a station). The card can include several LEDs, each being associated with one piece of information for example a letter in an optical fiber. And one piece of information can be selected and/or displayed according to the frequency emitted by a terminal.

1. An electronic module comprising at least one unpackaged integrated circuit chip connected to conductive tracks of an insulating support by first electric connections and at least one electroluminescent diode connected to the conductive tracks by means of second electric connections, wherein an assembly composed of at least the integrated circuit, the electroluminescent diode, the first and second electric connections and at least partially the conductive tracks is coated with a translucent resin forming a mechanical protection element for said assembly and a transmission element for the light emitted by said electroluminescent diode.

2. An electronic module comprising at least one electroluminescent diode connected by second electric connections to conductive tracks of an insulation support, said tracks forming at least one electromagnetic coil, wherein an the assembly formed by at least the electroluminescent diode, the second electric connections and at least partially the conductive tracks is coated with a translucent resin forming a mechanical protection of the assembly and for the transmission of the light emitted by said electroluminescent diode.

3. An electronic module according to claim 1, wherein said electroluminescent diode is a semiconductor chip directly supplied from a semiconductor wafer.

4. An electronic module according to claim 1, wherein said electroluminescent diode is of the CMS type, having the electroluminescent chip mounted on a support comprising connection tracks and a second coating of translucent protection, said diode being connected to the module by means of second electric connections.

5. An electronic module according to claim 1, wherein said electroluminescent diode it is connected in parallel to said integrated circuit.

6. An electronic module according to claim 1, wherein said mechanical protection has a bulging shape above the assembly.

7. An electronic module according to claim 1, wherein said resin is transparent.

8. An electronic module according to claim 1, wherein said resin comprises pigments the transmission band of which includes the emission wavelength of said electroluminescent diode.

9. An electronic module according to claim 1, wherein said resin comprises dopants having remanence properties and an excitation band comprising the emission wavelength of said electroluminescent diode, the dopants being capable of being loaded with energy upon the emission of said electroluminescent diode and of restituting such energy, on a time interval, in the form of a light having one or several proper wavelengths.

10. An electronic module according to claim 1, further including a resistor mounted in series with said electroluminescent diode.

11. An electronic module according to claim 1, wherein said integrated circuit is a contactless chip.

12. An electronic module according to claim 11, wherein said electroluminescent diode is directly supplied by an induction loop comprised in said module or not.

13. An electronic module according to claim 11, wherein said module includes a magnetic field detector and a controlled circuit of said electroluminescent diode according to the detection of said electromagnetic field.

14. An electronic module according to claim 13, wherein said controlled circuit delivers an electric signal to said electroluminescent diode, the frequency of which depends on the intensity of the electromagnetic field detected.

15. An electronic module according to claim 1, wherein said electroluminescent diode is directly connected to the supply terminals of said module.

16. An electronic device comprising an electronic module according to claim 1

17. An electronic device of the chip card type according to claim 16, wherein it includes a plastic support having an apparent cavity and wherein said electronic module is embedded in said cavity.

18. An electronic device of the chip card type according to claim 17, wherein said chip of said electronic module has contactless communication functions and wherein the electronic module is buried in the body of the chip card during the card lamination steps.

19. An electronic device of the chip card type according to claim 18, wherein said plastic support forms a brief guide capable of transmitting the light emitted by said electroluminescent diode.

20. An electronic device according to claim 16, wherein said device constitutes an USB key.

21. A manufacturing method for an electronic module comprising at least an integrated circuit chip connected to conductive tracks of an insulating support and at least one electroluminescent diode, wherein it comprises one step of coating the assembly composed of at least the integrated circuit and the electroluminescent diode with an insulating and translucent resin

22. A method according to claim 21, wherein during the said coating step said resin is deposited so as to give it requested radius of curvature.
